(19) United States
(12) Patent Application Publication
(10) Pub. No.: US 2026/0196401 A1
(43) Pub. Date: Jul. 9, 2026

(54) TRANSFORMER AND ELECTRONIC MODULES INCLUDING A TRANSFORMER

(71) Applicant: Murata Manufacturing Co., Ltd., Nagaokakyo-shi (JP)

(72) Inventors: Liqin NI, Westborough, MA (US); Zibran Aziz KHAN, Westborough, MA (US); Adolfo CASTILLO, Westborough, MA (US)

(21) Appl. No.: 19/440,227

(22) Filed: Jan. 5, 2026

Related U.S. Application Data
(60) Provisional application No. 63/742,113, filed on Jan. 6, 2025.

(51) Int. Cl. H01F 27/24; H01F 27/28; H05K 1/181

(52) U.S. Cl. CPC H01F 27/24; H01F 27/28; H05K 1/181; H05K 2201/1003

(57) ABSTRACT

A transformer includes a printed circuit board including a first main surface and a second main surface that are opposed to each other in a thickness direction of the printed circuit board, a primary winding provided in the printed circuit board, a secondary winding defined by a first copper stamp provided on the first main surface of the printed circuit board and a second copper stamp provided on the second main surface of the printed circuit board, and a magnetic core. The primary winding is sandwiched by the first copper stamp and the second copper stamp. The magnetic core extends through a coil opening of each of the primary winding and the secondary winding and through first and second cutouts of the printed circuit board.

### CROSS REFERENCE TO RELATED APPLICATIONS

This application claims the benefit of U.S. patent application Ser. No. 63/742,113 filed on Jan. 6, 2025. The entire contents of this application are hereby incorporated by reference.

### BACKGROUND OF THE INVENTION

### 1. Field of the Invention

The present invention relates to transformers and to electronic modules that include transformers. More specifically, the present invention relates to transformers and to electronic modules that include transformers that include transformer mounting configurations that streamline secondary winding manufacturing, especially for high current secondary windings that include copper stamps.

### 2. Description of the Related Art

A known transformer for high power/current applications includes a printed circuit board (PCB) primary winding for high voltages and a secondary winding for low voltages and high currents. The secondary winding is made of copper stamps. The copper stamps are mounted onto a main printed circuit board in the manufacturing process. It is known to use a separate PCB winding and a two-copper-stamp winding in a transformer. FIGS. 6A-6D show a comparative example illustrating the previous board mounting design by the inventors. As shown in FIGS. 6A-6D, the transformer 100 includes a magnetic core set 500, a main PCB 300, a primary winding that is provided in a separate PCB 101, and a secondary winding composed of two copper stamps 201, 202 which sandwich the primary winding in the PCB 101. The PCB 101 is connected to the main PCB 300 via through-hole pins 400, and the two copper stamps 201, 202 are directly mounted to the main PCB 300 by through-hole pins 204. Manufacturing this stacked structure, including the mounting of the PCB winding, requires time and can be costly. Moreover, such a stacked PCB structure has a relatively large profile.

An example of a known transformer is described in PCT Publication No. WO 2019/201302 A1, which, as shown in FIG. 2 thereof, discloses a planar transformer including first and second magnetic cores 21, 24, a plurality of PCB windings 22, and a plurality of flat copper foils 23, in which the first magnetic core 24, each PCB winding 22, each flat coil 23, and the second magnetic core 21 are coaxially assembled into the planar transformer. However, the following problems can arise with the planar transformer in PCT Publication No. WO 2019/201302 A1 when attempting to mount such a planar transformer in a larger module such as a DC-DC converter module.

In PCT Publication No. WO 2019/201302 A1, the planar transformer is separate from the main PCB of a power module, and a technique of combining and stacking multiple primary winding PCBs is described as shown in FIG. 2 of PCT Publication No. WO 2019/201302 A1. If multiple stacked primary winding PCBs are used for the planar transformer, it will be technically difficult to use this kind of primary winding PCB for a larger module (i.e., embedding the transformer into a larger PCB module). Further, because there are multiple primary winding PCBs, it is difficult to provide multiple secondary connections to each transformer primary winding board, and the copper stamps of the secondary windings cannot be connected to the same through-holes to reduce the number of manufacturing steps. It is desirable to provide a planar transformer that is a portion of or is integrated with a main printed circuit board of a power module. In other words, it would be desirable to provide a primary winding PCB of a transformer as a portion of the PCB of a larger power module. It would be further desirable to reduce the cost of manufacturing by employing the main board PCB for the primary winding, and streamline the secondary winding manufacturing, especially for high current secondary windings that include copper stamps.

### SUMMARY OF THE INVENTION

Example embodiments of the present invention provide transformers which reduce the cost of manufacturing by employing the printed circuit board for the primary winding and various mounting techniques to streamline the secondary winding manufacturing, especially for high current secondary windings that include copper stamps. Moreover, the transformers according to the example embodiments of the present invention provide a robust structure with a reduced profile that is easy to assemble.

Example embodiments of the present invention further provide transformers that are able to be integrated into and be part of a larger system module while maintaining a compact and small size.

According to an example embodiment of the present invention, a transformer includes a printed circuit board including a first main surface and a second main surface that are opposed to each other in a thickness direction of the printed circuit board, a primary winding provided in the printed circuit board, a secondary winding defined by a first copper stamp provided on the first main surface of the printed circuit board and a second copper stamp provided on the second main surface of the printed circuit board, and a magnetic core. The primary winding is sandwiched by the first copper stamp and the second copper stamp. A first portion of the magnetic core extends through a coil opening of each of the primary winding and the secondary winding in the thickness direction, a second portion of the magnetic core overlaps with each of the primary winding and the secondary winding in the thickness direction, a third portion of the magnetic core extends through a first cutout of the printed circuit board in the thickness direction, and a fourth portion of the magnetic core extends through a second cutout of the printed circuit board in the thickness direction.

The first copper stamp and the second copper stamp can be surface mounted to the printed circuit board. The first copper stamp and the second copper stamp can be connected through same through-holes of the printed circuit board. The first copper stamp and the second copper stamp can be connected to different through-holes of the printed circuit board. The first copper stamp and the second copper stamp can be connected by screws extending through same through-holes of the printed circuit board. The first copper stamp and the second copper stamp can be connected by screws extending through different through-holes of printed circuit board.

A first insulation material can be provided between the first copper stamp and the magnetic core, and a second insulation material can be provided between the printed circuit board and the second copper stamp. A spacer can be provided between the first copper stamp and the magnetic core.

According to an example embodiment of the present invention, a circuit board module includes a printed circuit board including a first main surface and a second main surface that are opposed to each other in a thickness direction of the printed circuit board and a plurality of transformers integrated and mounted on the printed circuit board. Each of the plurality of transformers includes a primary winding provided in the printed circuit board, a secondary winding defined by a first copper stamp provided on the first main surface of the printed circuit board and a second copper stamp provided on the second main surface of the printed circuit board, and a magnetic core. In each of the plurality of transformers, the primary winding is sandwiched by the first copper stamp and the second copper stamp, a first portion of the magnetic core extends through a coil opening of each of the primary winding and the secondary winding in the thickness direction, a second portion of the magnetic core overlaps with each of the primary winding and the secondary winding in the thickness direction, a third portion of the magnetic core extends through a first cutout of the printed circuit board in the thickness direction, and a fourth portion of the magnetic core extends through a second cutout of the printed circuit board in the thickness direction.

The plurality of transformers can include a first transformer and a second transformer that are adjacent to each other, and the third portion of the magnetic core of the first transformer and the fourth portion of the magnetic core of the second transformer can share a same cutout of the printed circuit board.

According to an example embodiment of the present invention, an electronic module includes a substrate including a substrate opening and first and second cutouts, an electronic component located on the substrate, and a transformer connected to the electronic component and including a primary winding on or in the substrate that extends around the substrate opening; a secondary winding connected to the substrate and including first and second stamps on opposing sides of the substrate, each of the first and the second stamps includes a stamp opening; and a magnetic core that extends through the substrate opening, through the second and the third cutouts, and through each stamp opening in the first and the second stamps.

The first and the second stamps can be surface mounted to the substrate. The substrate can include through holes. The first and the second stamps can extend through different through holes. The first and the second stamps can extend through same through holes. The electronic module can further include fasteners that extend through the through holes to connect the first and the second stamps to the substrate. Different fasteners can connect the first and the second stamps to the substrate. Same fasteners can connect the first and the second stamps to the substrate.

The electronic module can further include an additional transformer that includes an additional magnetic core, where the additional magnetic core can extend through the third cutout adjacent to the magnetic core. The electronic module can be a power module.

According to example embodiments of the present invention, it is possible to provide transformers which reduce the cost of manufacturing by employing the printed circuit board for the primary winding and various mounting techniques to streamline the secondary winding manufacturing, especially for high current secondary windings that include copper stamps. Moreover, the transformers according to the example embodiments of the present invention disclosed herein provide a robust structure with a reduced profile, are easy to assemble, and simplify the manufacturing process.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1A is an isometric view from above of a transformer according to a first example embodiment of the present invention in which two copper stamps are surface mounted to a PCB.

FIG. 1B is an isometric view from below of the transformer of FIG. 1A.

FIG. 1C is a top view of the transformer of FIG. 1A.

FIG. 1D is a cross-sectional view taken along line A-A of the transformer of FIG. 1C.

FIG. 1E is an exploded view of the transformer of FIG. 1A according to the first example embodiment in which the copper stamps of the secondary winding are surface mounted to the top and bottom of the PCB.

FIG. 1F is an equivalent circuit diagram of the transformer according to the first example embodiment in a first circuit configuration.

FIG. 1G is an equivalent circuit diagram of the transformer according to the first example embodiment in a second circuit configuration.

FIG. 2A is an isometric view from above of a transformer according to a second example embodiment of the present invention in which two copper stamps are connected to a PCB using the same through-holes.

FIG. 2B is an isometric view from below of the transformer of FIG. 2A.

FIG. 2C is a top view of the transformer of FIG. 2A.

FIG. 2D is a cross-sectional view taken along line A-A of the transformer of FIG. 2C.

FIG. 2E is an exploded view of the transformer of FIG. 2A according to the second example embodiment in which the copper stamps of the secondary winding are connected to the PCB using the same through-holes.

FIG. 2F is an equivalent circuit diagram of the transformer according to the second example embodiment.

FIG. 3A is an isometric view from above of a transformer according to a third example embodiment of the present invention in which two copper stamps are connected to a PCB by using different through-holes.

FIG. 3B is an isometric view from below of the transformer of FIG. 3A.

FIG. 3C is a top view of the transformer of FIG. 3A.

FIG. 3D is a cross-sectional view taken along line A-A of the transformer of FIG. 3C.

FIG. 3E is an exploded view of the transformer of FIG. 3A according to the third example embodiment in which the copper stamps of the secondary winding are connected to the PCB by using different through-holes.

FIG. 3F is an equivalent circuit diagram of the transformer according to the third example embodiment in a first circuit configuration.

FIG. 3G is an equivalent circuit diagram of the transformer according to the third example embodiment in a second circuit configuration.

FIG. 4A is an isometric view from above of a transformer according to a fourth example embodiment of the present invention in which two copper stamps are mounted to a PCB using screws and nuts.

FIG. 4B is an isometric view from below of the transformer of FIG. 4A.

FIG. 4C is a top view of the transformer of FIG. 4A.

FIG. 4D is a cross-sectional view taken along line A-A of the transformer of FIG. 4C.

FIG. 4E is an exploded view of the transformer of FIG. 4A according to the fourth example embodiment in which the copper stamps of the secondary winding are mounted to the top and bottom of the PCB using screws and nuts.

FIG. 4F is an equivalent circuit diagram of the transformer according to the fourth example embodiment.

FIG. 5A is an isometric view from above of a transformer according to a fifth example embodiment of the present invention in which two copper stamps are mounted to a PCB using screws and threaded inserts.

FIG. 5B is an isometric view from below of the transformer of FIG. 5A.

FIG. 5C is a top view of the transformer of FIG. 5A.

FIG. 5D is a cross-sectional view taken along line A-A of the transformer of FIG. 5C.

FIG. 5E is an exploded view of the transformer of FIG. 5A according to the fifth example embodiment in which the copper stamps of the secondary winding are mounted to the top and bottom of the PCB using screws and threaded inserts.

FIG. 5F is an equivalent circuit diagram of the transformer according to the fifth example embodiment in a first circuit configuration.

FIG. 5G is an equivalent circuit diagram of the transformer according to the fifth example embodiment in a second circuit configuration.

FIG. 6A is an isometric view from above of a transformer according to a comparative example.

FIG. 6B is an isometric view from below of the transformer of FIG. 6A.

FIG. 6C is a top view of the transformer of FIG. 6A.

FIG. 6D is a cross-sectional view taken along line A-A of the transformer of FIG. 6C.

FIG. 7A is an isometric view showing a plurality of transformers mounted on a main circuit board according to an example embodiment of the present invention.

FIG. 7B is a plan view showing a plurality of transformers mounted on a main circuit board according to an example embodiment of the present invention.

FIG. 7C is an isometric view of an electronic module including a plurality of transformers mounted on a main circuit board according to an example embodiment of the present invention.

FIG. 7D is a plan view showing an electronic module including a plurality of transformers mounted on a main circuit board according to an example embodiment of the present invention.

### DETAILED DESCRIPTION OF EXAMPLE EMBODIMENTS

Hereinafter, example embodiments of the present invention will be illustrated with several specific examples with reference to the drawings. The same components are denoted by the same reference characters in the drawings. Although example embodiments are separately illustrated for convenience in view of description of points or ease of understanding, partial replacement or combination of configurations illustrated in different example embodiments is possible. In second and subsequent example embodiments, a description of some of the matters in common with the first example embodiment will be omitted, and only differences will be described. In particular, the same operational effects by the same configurations will not be mentioned one by one in each example embodiment.

### First Example Embodiment

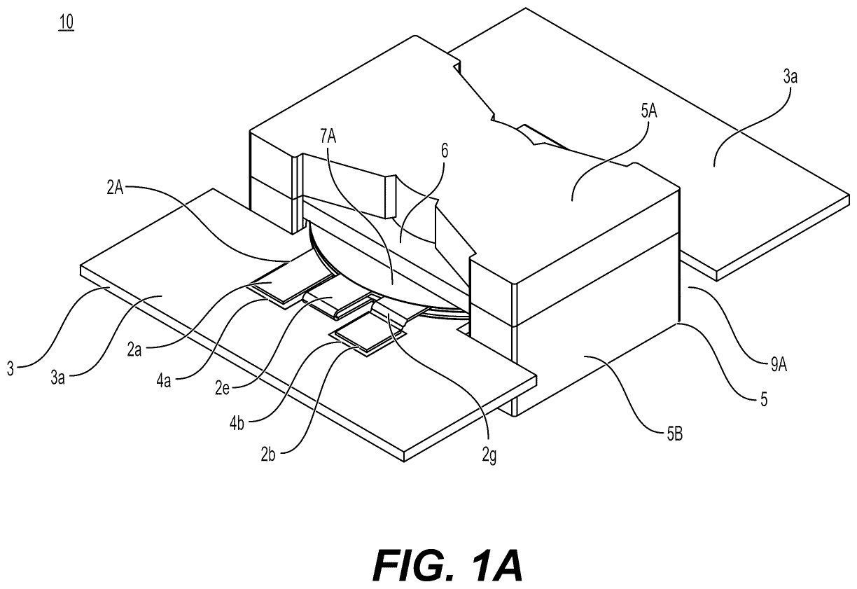

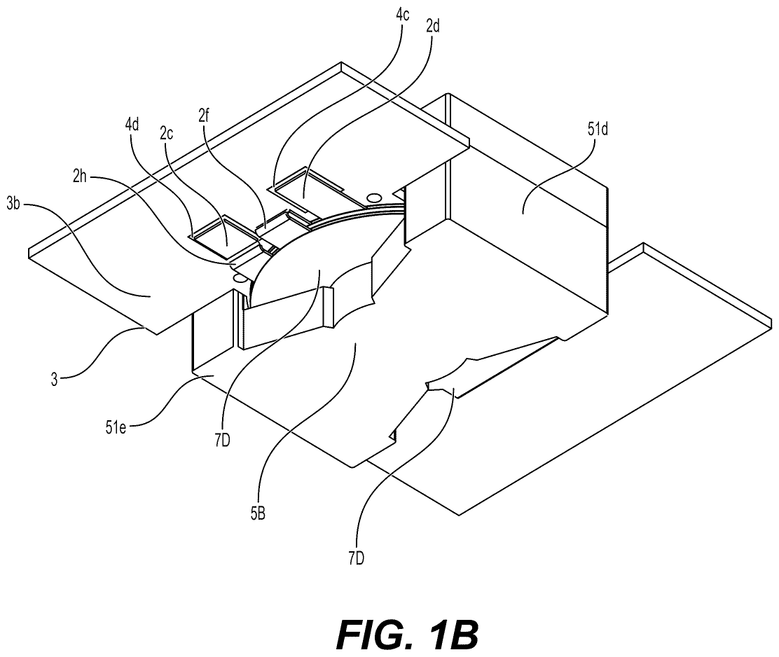

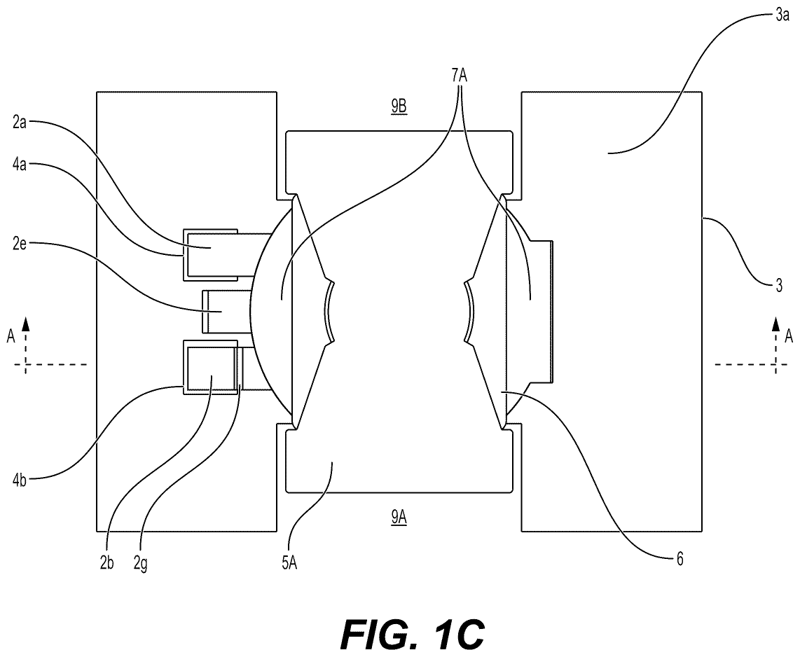

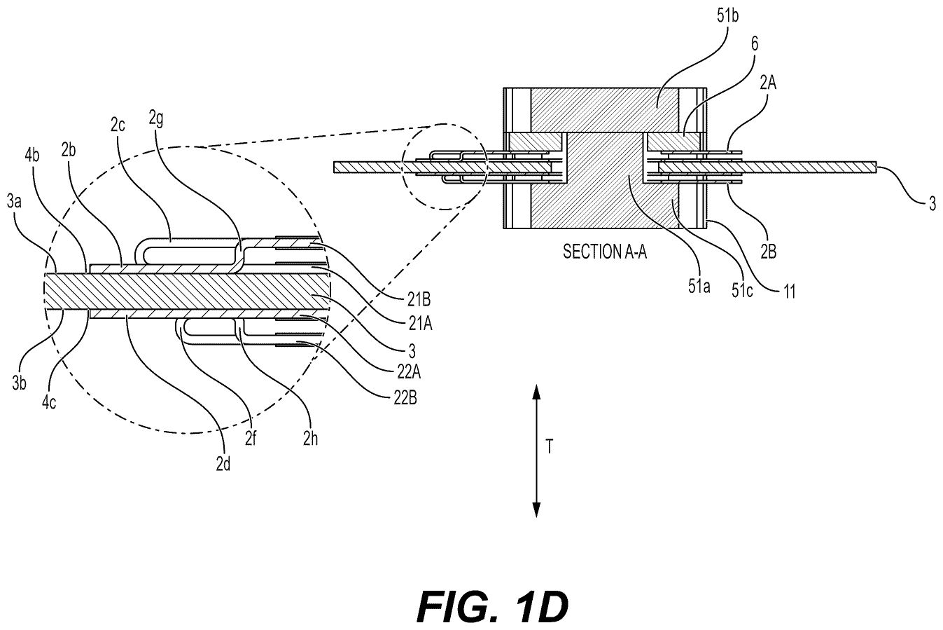

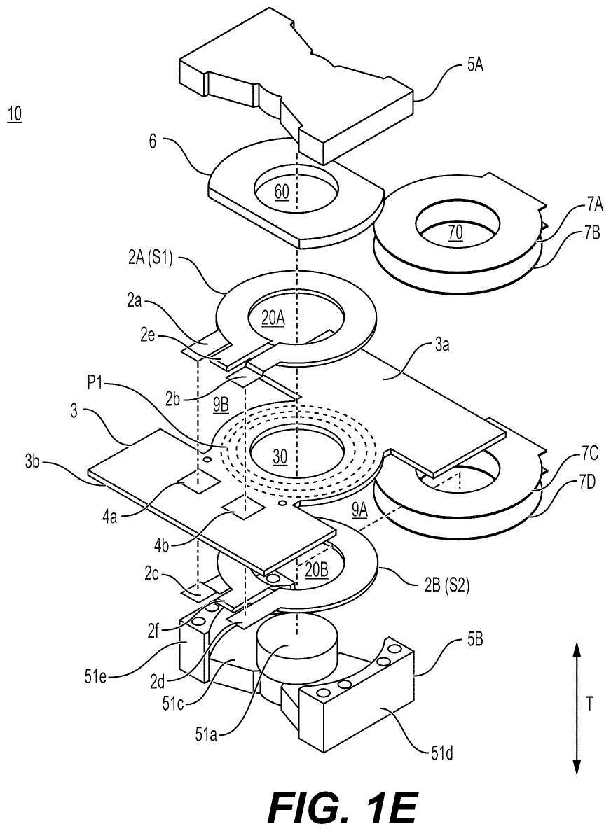

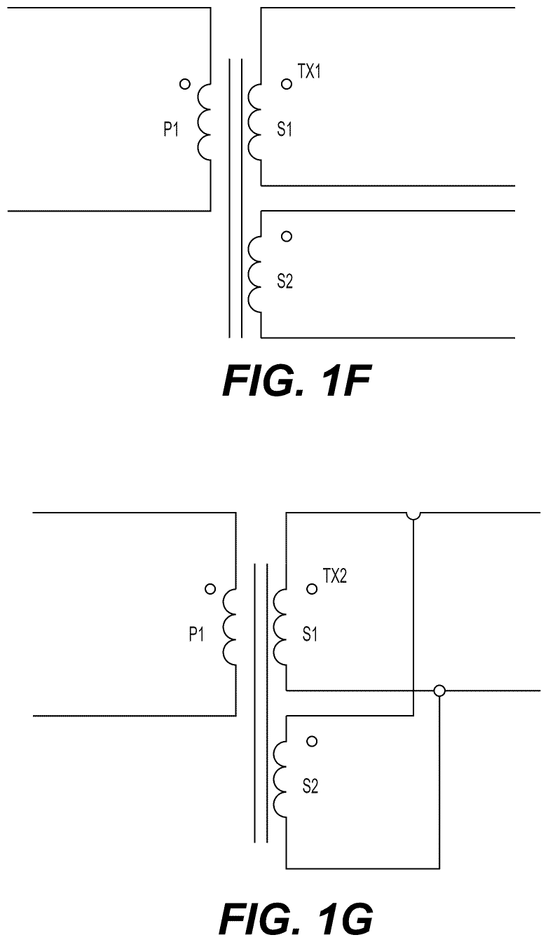

FIGS. 1A-1E show a transformer mounting configuration according to a first example embodiment in which copper stamps 2A, 2B of the secondary winding 2 are surface mounted to the top and bottom of a PCB 3.

FIG. 1A is an isometric view from above of a transformer 10 according to a first example embodiment of the present invention in which two copper stamps 2A, 2B are surface mounted to a PCB 3. FIG. 1B is an isometric view from below of the transformer 10 of FIG. 1A.

FIG. 1C is a top view of the transformer 10 of FIG. 1A. FIG. 1D is a cross-sectional view taken along line A-A of the transformer 10 of FIG. 1C. FIG. 1E is an exploded view of the transformer 10 of FIG. 1A according to the first example embodiment in which the copper stamps 2A, 2B of the secondary winding 2 are surface mounted to the top and bottom of the PCB 3.

As shown in FIGS. 1A-1E, the transformer 10 includes a magnetic core set 5 (5A, 5B), a primary winding P1 which is formed as part of a printed circuit board (PCB) 3, and a secondary winding 2 composed of two copper stamps 2A, 2B. The primary winding P1 is sandwiched by the first copper stamp 2A and the second copper stamp 2B of the secondary winding 2.

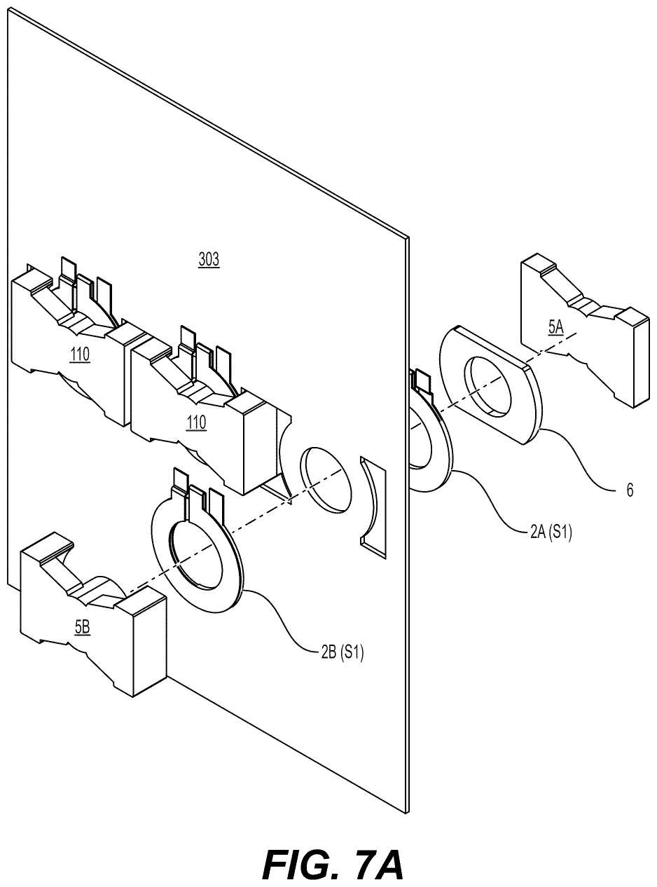

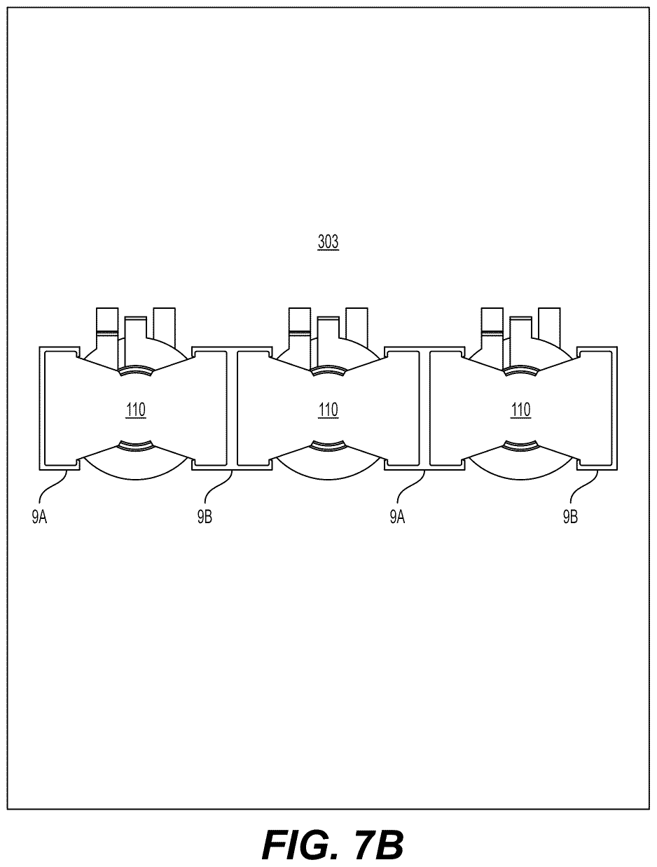

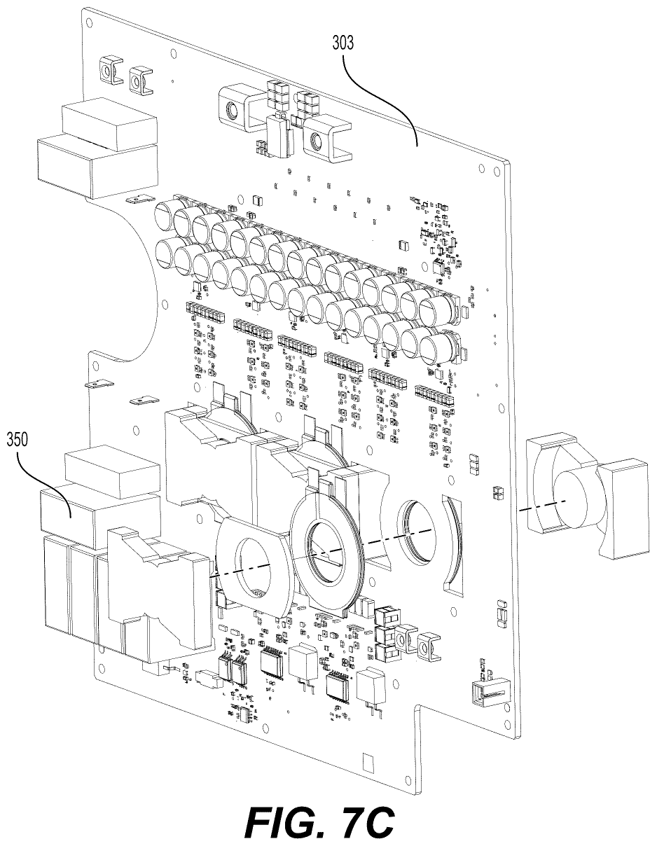

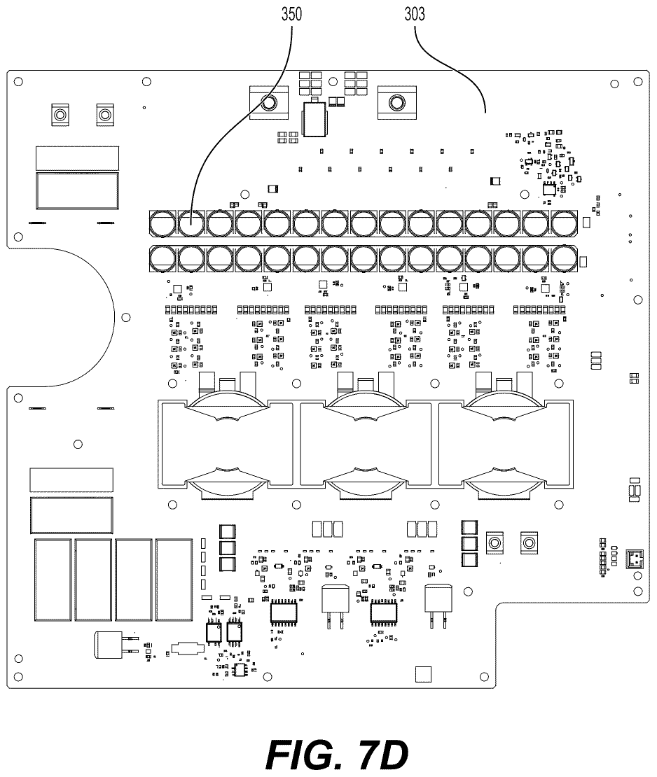

The PCB 3 includes a first main surface 3a and a second main surface 3b that are opposed to each other in a thickness direction T of the PCB 3. The PCB 3 also includes a PCB opening 30, a first cutout 9A, and a second cutout 9B. The cutouts 9A, 9B are shown as being open in FIGS. 1A-1E. Alternatively, the cutouts 9A, 9B can be closed (see, for example, the cutouts in FIGS. 7A and 7B). The cutouts 9A, 9B can have any suitable shape. The PCB 3 includes an insulating substrate which may be made of, for example FR-4. The PCB 3 includes one or more conductive layers including the primary winding P1 that is provided within or on the PCB 3. Instead of using a printed circuit board, other types of substrates may be used in place a PCB 3.

The magnetic core set 5 includes an upper (top) portion 5A and a lower (bottom) portion 5B. The secondary winding 2 is defined by a first copper stamp 2A provided on the first main surface (top surface) of the PCB 3 and by a second copper stamp 2B provided on the second main surface (bottom surface) of the PCB 3. As shown in FIGS. 1D and 1E, a first portion 51a of the magnetic core 5 extends through a coil opening 30 of the primary winding P1, a coil opening 20A of the first copper stamp 2A, and a coil opening 20B of the second copper stamp 2B in the thickness direction T. A second portion including an upper second portion 51b and a lower second portion 51c of the magnetic core 5 overlaps with each of the primary winding P1 and the secondary winding 2 in the thickness direction T. A third portion 51d of the magnetic core 5 extends through a first cutout 9A of the PCB 3 in the thickness direction, and a fourth portion 51e of the magnetic core 5 extends through a second cutout 9B of the PCB 3 in the thickness direction T. As shown in FIG. 1D, the magnetic core 5 may include a casing 11 that surrounds the inner magnetic core portions 51a, 51b and 51c.

Each of the first copper stamp 2A and the second copper stamp 2B may be formed of a unitary metal piece construction. As shown in FIGS. 1A-1E, the first copper stamp 2A includes a first layer 21A and a second layer 21B, a first intermediate bent portion 2e that is connected between the first layer 21A and the second layer 21B, a first contact portion 2a provided at one end of the first copper stamp 2A, and a second contact portion 2b provided at the other end of the first copper stamp 2A. Similarly, the second copper stamp 2B includes a first layer 22A and a second layer 22B, a second intermediate bent portion 2f that is connected between the first layer 22A and the second layer 22B, a third contact portion 2c provided at one end of the second copper stamp 2B, and a fourth contact portion 2d provided at the other end of the second copper stamp 2B.

As shown in FIGS. 1A-1E, contact pads 4a, 4b, 4c, 4d are provided on the first and second main surfaces 3a, 3b of the PCB 3. A first contact pad 4a and a second contact pad 4b are provided on the first main surface 3a, and a third pad 4c and a fourth contact pad 4d are provided on the second main surface 3b. The first copper stamp 2A includes a bent portion 2g that is connected between the second contact portion 2b and the second layer 21B of the first copper stamp 2A. Similarly, the second copper stamp 2B includes a bent portion 2h that is connected between the third contact portion 2c and the second layer 22B of the second copper stamp 2B.

Each of the contact portions 2a, 2b, 2c, 2d are joined to the contact pads 4a, 4b, 4c, 4d, respectively. The contact portions 2a, 2b, 2c, 2d may be bonded to the contact pads 4a, 4b, 4c, 4d using solder, a conduct adhesive, welding, or other suitable means. Accordingly, the first and second copper stamps 2A, 2B of the secondary winding 2 are surface mounted to the top and bottom surfaces of the PCB 3 that includes the primary winding P1.

As shown in FIGS. 1A and 1E, a spacer 6 including a hole opening 60 may be provided between the second copper stamp 2A and the upper magnetic core portion 5A.

Layers of insulation material 7 (7A-7D) can sandwich the copper stamps 2A, 2B, as shown in FIG. 1E. Alternatively, according to an example embodiment of the present invention, a first insulation material 7A is provided between the first copper stamp 2A and the magnetic core portion 5A, and a second insulation material 7C is provided between the PCB 3 and the second copper stamp 2B. The layers of insulation material 7 (7A-7D) may be made of Kapton™ tape or other suitable materials. The layers of insulation material 7 (7A-7D) each include an insulation material opening 70 in which the magnetic portion 51a extends through. The layers of insulations materials 7 (7A-7D) are optional and are not required.

FIG. 1F is an equivalent circuit diagram of the transformer 10 according to the first example embodiment in a first circuit configuration. As shown in FIG. 1F, the primary winding P1 is magnetically coupled to each of the secondary windings S1(2B) and S2(2A) to form a transformer TX1. The two secondary windings S1(2B) and S2(2A) are independent within the transformer TX1 as shown in FIG. 1F. However, the two secondary windings S1(2B) and S2(2A) can be connected in parallel or in series with each other depending on the connections in an external circuit connected to the transformer TX1.

FIG. 1G is an equivalent circuit diagram of the transformer 10 according to the first example embodiment in a second circuit configuration. As shown in FIG. 1G, the primary winding P1 is magnetically coupled to each of the secondary windings S1(2B) and S2(2A) to form a transformer TX2. In this alternative example, the secondary windings S1(2B) and S2(2A) are connected in parallel.

### Second Example Embodiment

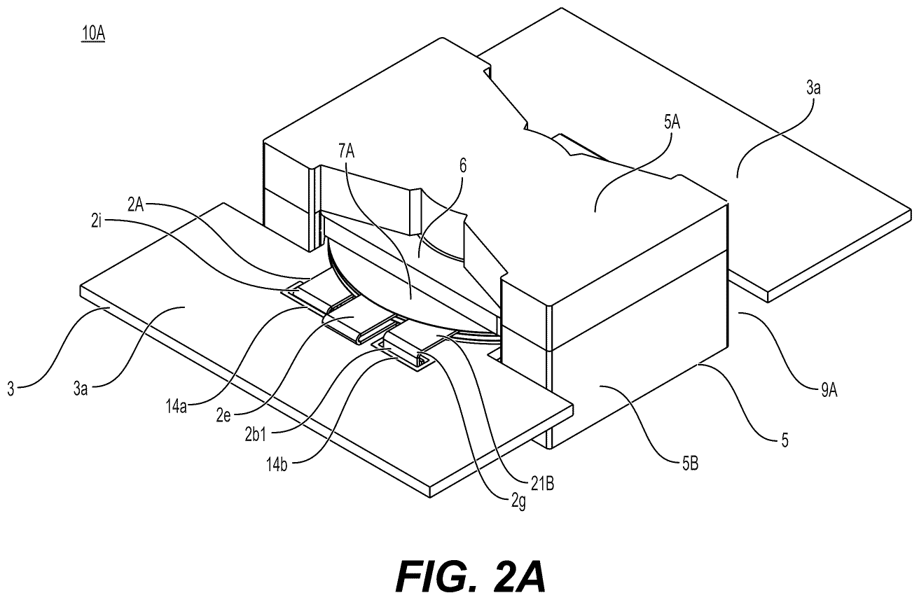

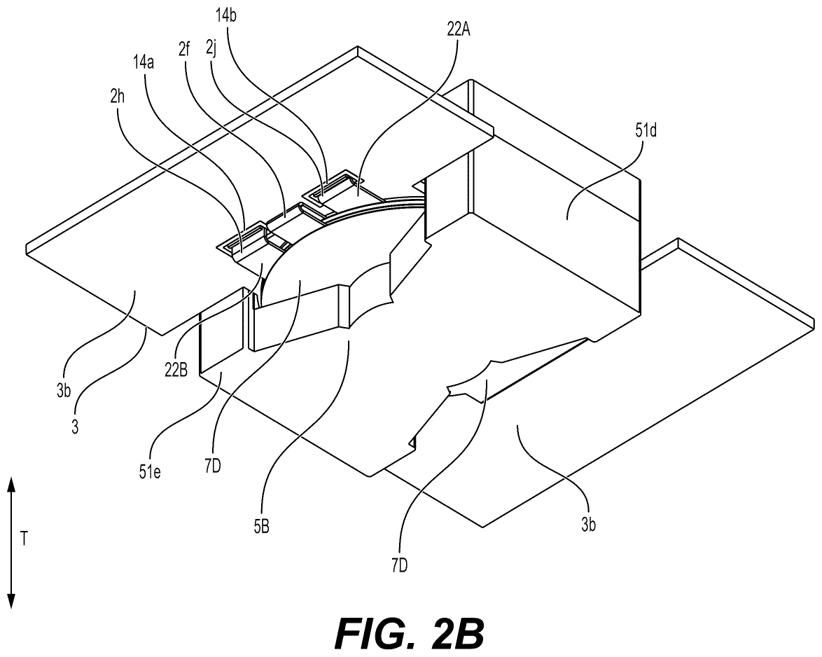

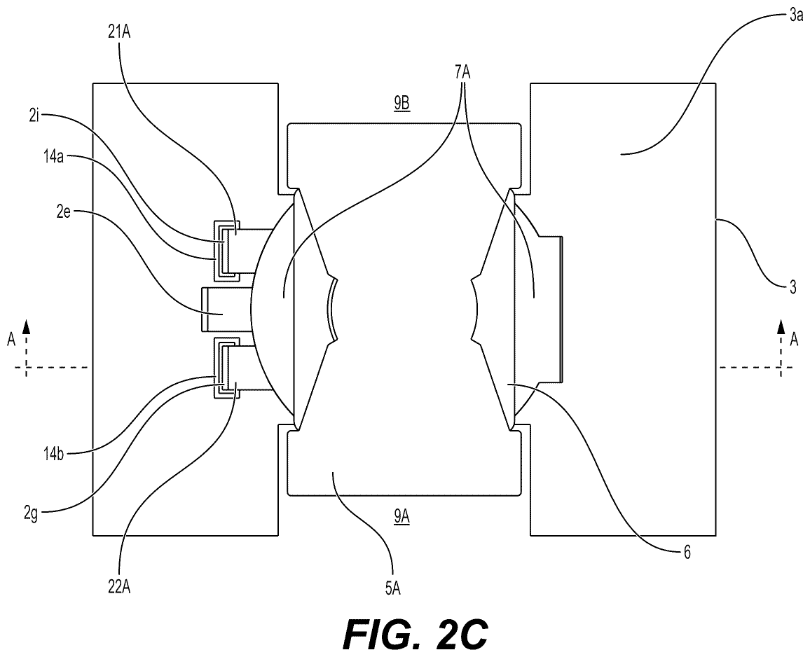

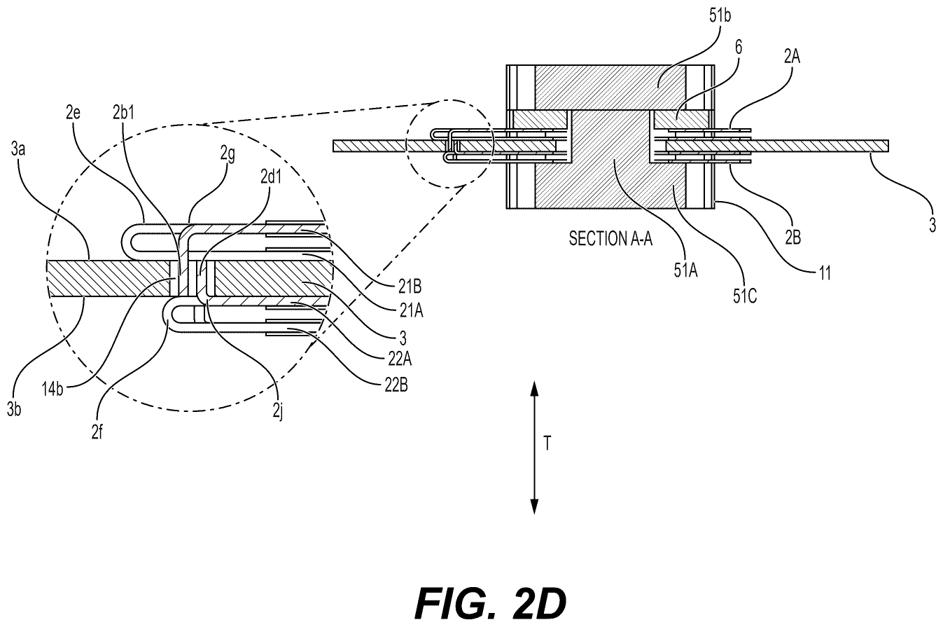

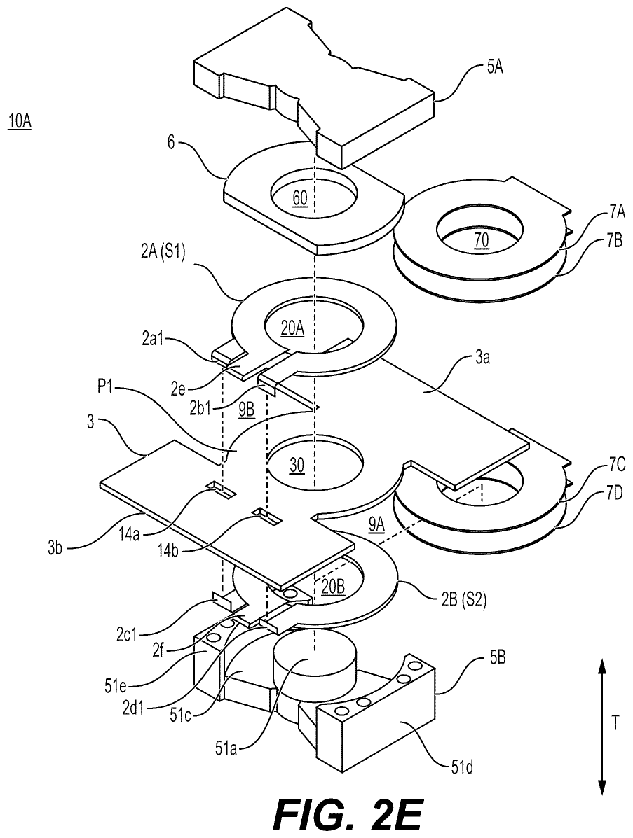

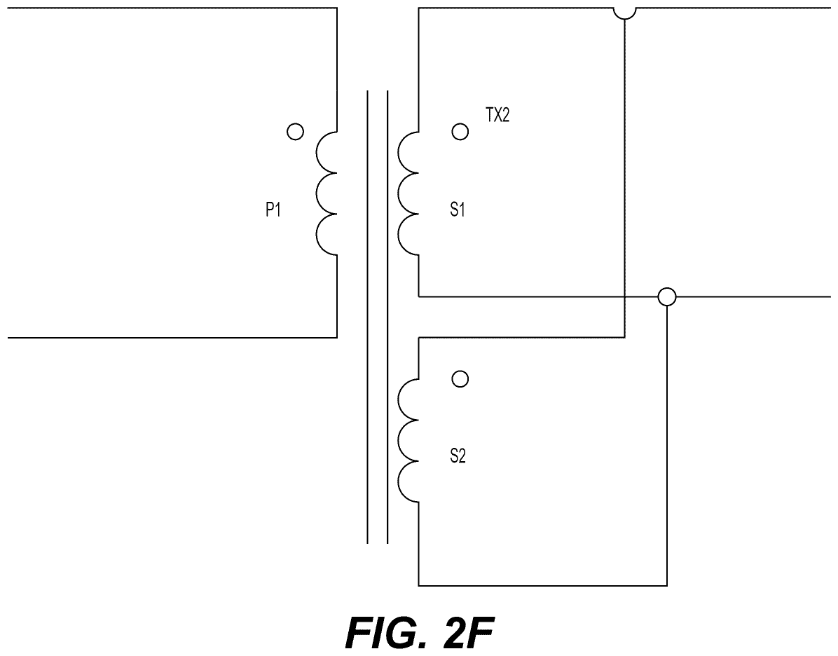

FIGS. 2A-2E show a transformer mounting configuration according to a second example embodiment in which the copper stamps 2A, 2B of the secondary winding 2 are mounted to the PCB 3 by extending through the same through-holes 14a, 14b. In the second example embodiment, the top and bottom copper stamps 2A, 2B of the secondary winding 2 are connected through the same through-hole 14a or 14b. In the second example embodiment, the transformer 10A includes a magnetic core set 5, a primary winding P1 which is part of the PCB 3, and a secondary winding 2 composed of two copper stamps 2A, 2B, similar to the first example embodiment. Hereinafter, description of some of the components or elements having the same numeral characters as the first example embodiment will be omitted.

FIG. 2A is an isometric view from above of a transformer 10A according to the second example embodiment of the present invention in which two copper stamps 2A, 2B are connected to a PCB 3 using the same through-holes 14a, 14b. FIG. 2B is an isometric view from below of the transformer 10A of FIG. 2A. FIG. 2C is a top view of the transformer 10A of FIG. 2A. FIG. 2D is a cross-sectional view taken along line A-A of the transformer of FIG. 2C. FIG. 2E is an exploded view of the transformer mounting configuration according to the second example embodiment in which the copper stamps of the secondary winding are mounted to the PCB through the same through-holes.

As shown in FIGS. 2A-2E, according to the second example embodiment of the present invention, the PCB 3 includes first and second through-holes 14a, 14b. The first and second through-holes 14a may be coated or filled with a conductive material. As shown in FIGS. 1A-1E, instead of the contact portions 2a, 2b, 2c, 2d of the first example embodiment which are surface mounted, the first and second copper stamps 2A, 2B include contact portions 2a1, 2b1, 2c1, and 2d1 that vertically extend into the through-holes 14a, 14b. The first copper stamp 2A includes a first contact portion 2a1 provided at one end and a second contact portion 2b1 provided at the other end of the first copper stamp 2A. Similarly, the second copper stamp 2B includes a third contact portion 2c1 provided at one end and a fourth contact portion 2d1 provided at the other end of the second copper stamp 2B.

As shown in FIGS. 2A-2E, the first contact portion 2a1 vertically extends into the first through-hole 14a, and the second contact portion 2b1 vertically extends into the second through-hole 14b. Likewise, the third contact portion 2c1 vertically extends into the first through-hole 14a, and the fourth contact portion 2d1 vertically extends into the second through-hole 14b. Accordingly, the first contact portion 2a1 of the first copper stamp 2A and the third contact portion 2c1 of the second copper stamp 2B are connected to each other in the same through-hole 14a, and the second contact portion 2b1 of the first copper stamp 2A and the fourth contact portion 2d1 of the second copper stamp 2B are connected to each other in the same through-hole 14b.

As shown in FIGS. 2A-2E, the first copper stamp 2A includes a bent portion 2i that is connected between the contact portion 2a1 and the first layer 21A of the first copper stamp 2A, and a bent portion 2g that is connected between the contact portion 2b1 and the second layer 21B of the first copper stamp 2A. Similarly, the second copper stamp 2B includes a bent portion 2h that is connected between the contact portion 2c1 and the second layer 22B of the second copper stamp 2B, and a bent portion 2j that is connected between the contact portion 2d1 and the first layer 22A of the second copper stamp 2B.

In accordance with the second example embodiment described above, the first copper stamp 2A and the second copper stamp 2B are connected through the same through-holes 14a, 14B of the PCB 3.

FIG. 2G is an equivalent circuit diagram of the transformer 10A according to the second example embodiment. As shown in FIG. 2G, the primary winding P1 is magnetically coupled to each of the secondary windings S1(2B) and S2(2A) to form a transformer TX2. In this example, the secondary windings S1(2B) and S2(2A) are connected in parallel.

### Third Example Embodiment

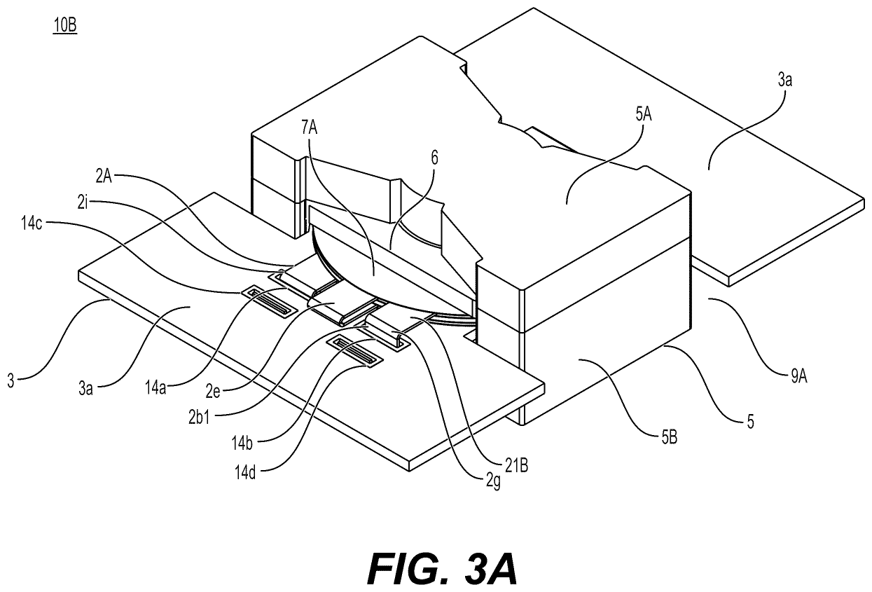

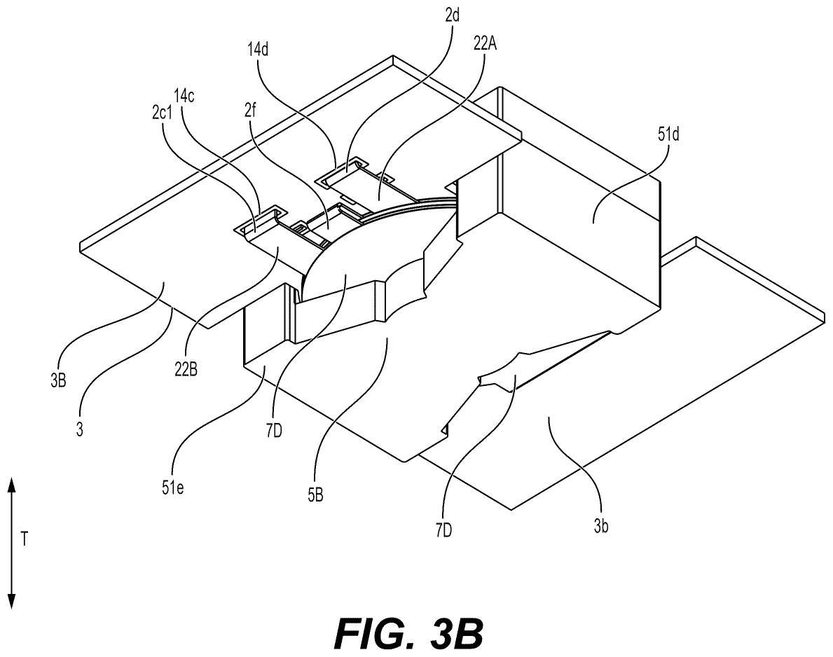

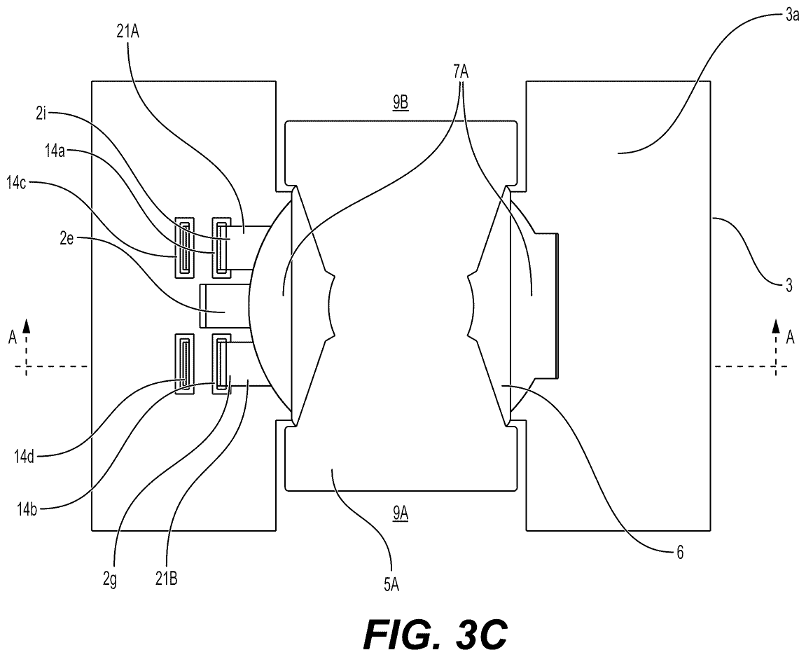

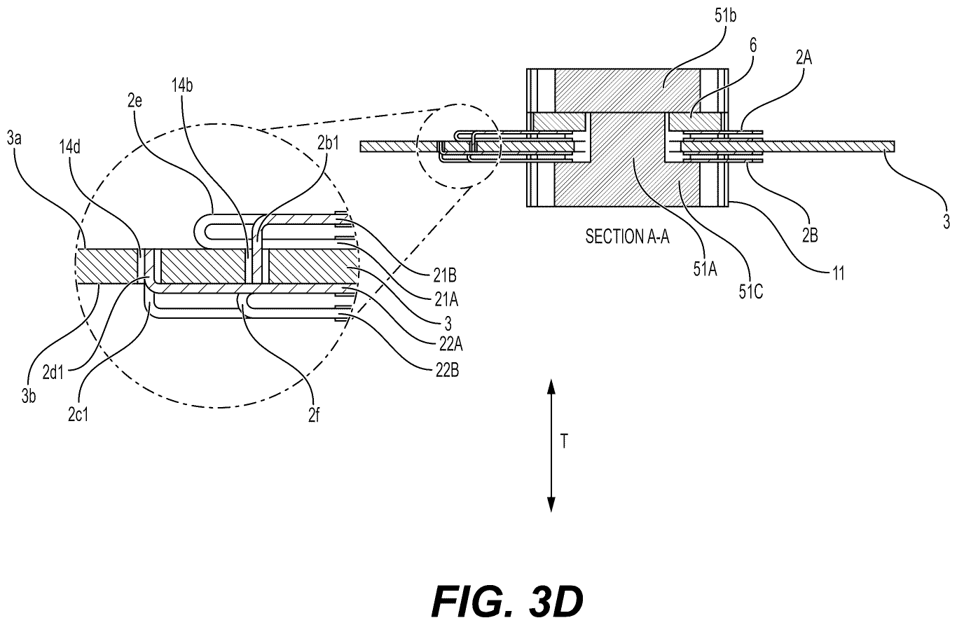

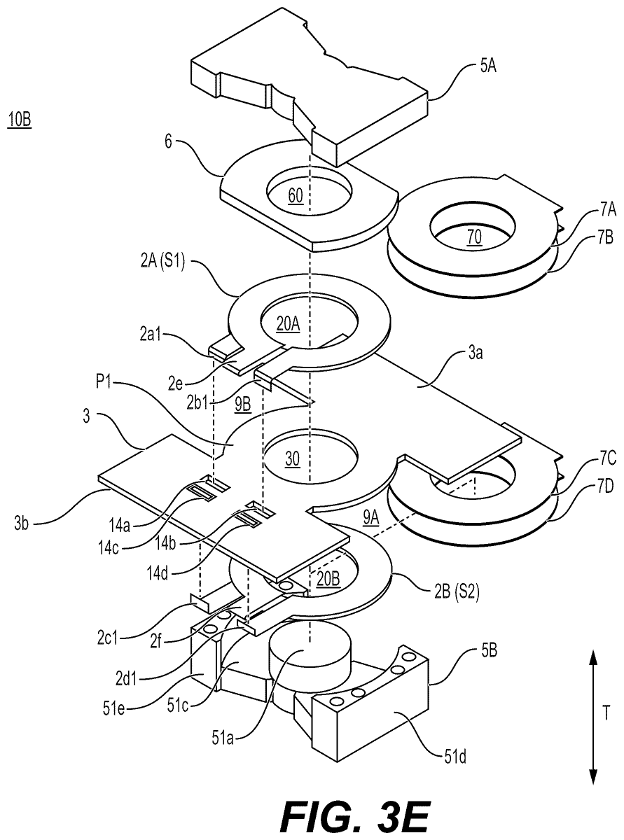

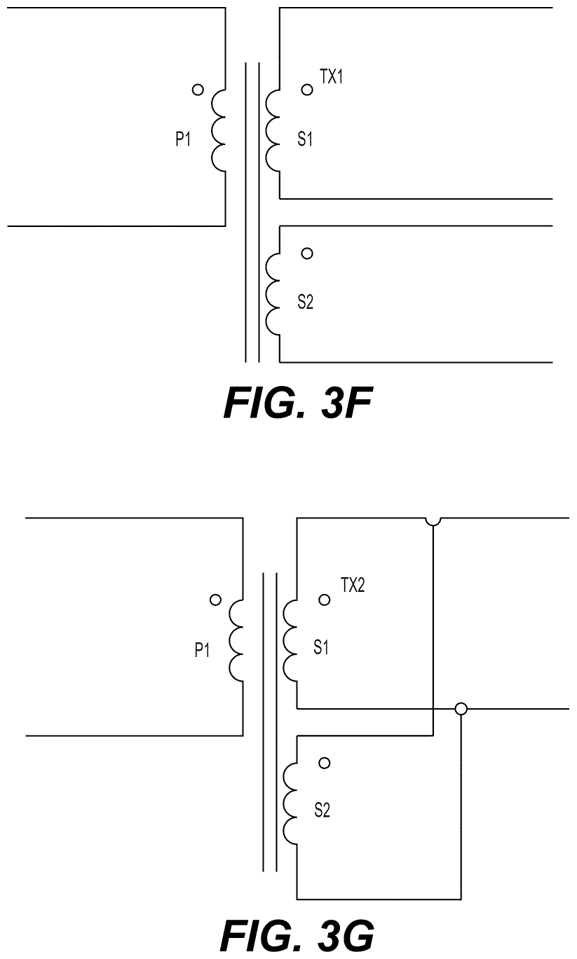

FIGS. 3A-3E show a transformer mounting configuration according to a third example embodiment in which the top and bottom copper stamps 2A and 2B of the secondary winding 2 are mounted to the PCB 3 through different through-holes 14a, 14b, 14c, 14d.

FIG. 3A is an isometric view from above of a transformer 10B according to a third example embodiment of the present invention in which two copper stamps 2A, 2B are connected to a PCB 3 by using different through-holes 14a, 14b, 14c, 14d. FIG. 3B is an isometric view from below of the transformer 10B of FIG. 3A. FIG. 3C is a top view of the transformer 10B of FIG. 3A. FIG. 3D is a cross-sectional view taken along line A-A of the transformer 10B of FIG. 3C. FIG. 3E is an exploded view of the transformer mounting configuration according to the third example embodiment in which the copper stamps 2A, 2B of the secondary winding 2 are mounted to the PCB 3 through different through-holes 14a, 14b, 14c, 14d.

As shown in FIGS. 3A-3E, the PCB 3 of the third example embodiment is different from the PCB 3 of the second example embodiment in that PCB 3 of the third example includes third and fourth through-holes 14c, 14d in addition to the first and second through-holes 14a, 14b. The second copper stamp 2B is structured accordingly to utilize the third and fourth through-holes 14c, 14d.

In the third example embodiment, similar to the second example embodiment, each of the through-holes 14a, 14b, 14c, 14d may be coated or filled with a conductive material.

As shown in FIGS. 3A-3E, according to the third example embodiment of the present invention, instead of the second copper stamp 2B connecting to and extending through the through-holes 14a, 14b as in the second example embodiment, the second copper stamp 2B connects to and extends through the through-holes 14c, 14d which are different from the through-holes 14a, 14b which the first copper stamp 2A connects to.

As shown in FIGS. 3A-3E, the third contact portion 2c1 vertically extends into the third through-hole 14c, and the fourth contact portion 2d1 vertically extends into the fourth through-hole 14d. Accordingly, with the second example embodiment described above, the first copper stamp 2A and the second copper stamp 2B are connected to the PCB 3 using different through-holes 14a, 14b, 14c, 14d. In FIG. 3D, the through-hole 14 b and the through-hole 14d may be connected within the PCB 3 via PCB copper traces (not shown), thereby providing an electrical connection between coil S1 and coil S2 as shown in FIG. 3G.

FIG. 3F is an equivalent circuit diagram of the transformer 10B according to the third example embodiment in a first circuit configuration. As shown in FIG. 3F, the primary winding P1 is magnetically coupled to each of the secondary windings S1(2B) and S2(2A) to form a transformer TX1. The two secondary windings S1(2B) and S2(2A) are independent within the transformer TX1 as shown in FIG. 3F. However, the two secondary windings S1(2B) and S2(2A) can be connected in parallel or in series with each other depending on the connections in an external circuit connected to the transformer TX1.

FIG. 3G is an equivalent circuit diagram of the transformer 10B according to the third example embodiment in a second circuit configuration. As shown in FIG. 3G, the primary winding P1 is magnetically coupled to each of the secondary windings S1(2B) and S2(2A) to form a transformer TX2. In this alternative example, the secondary windings S1(2B) and S2(2A) are connected in parallel.

### Fourth Example Embodiment

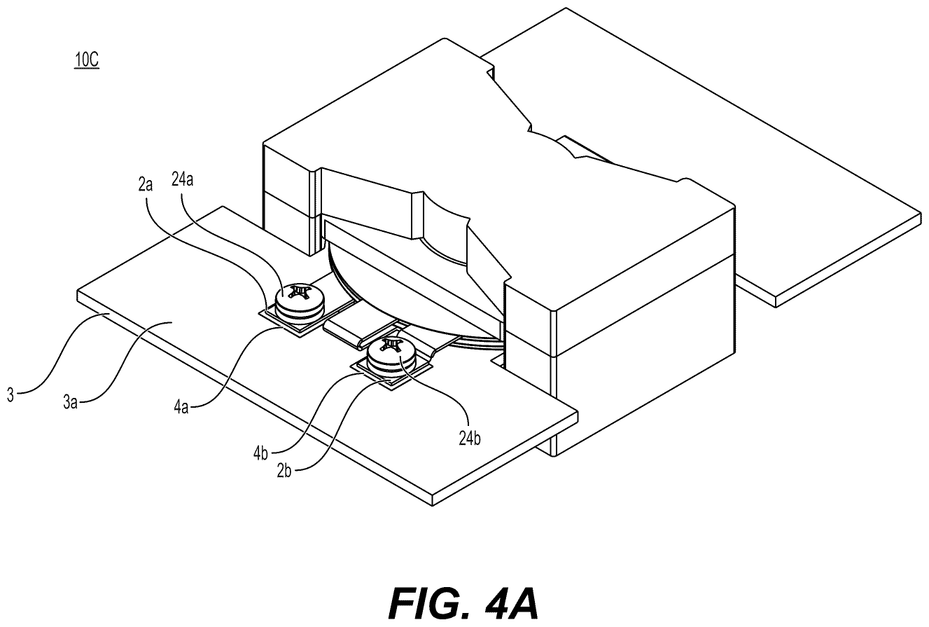

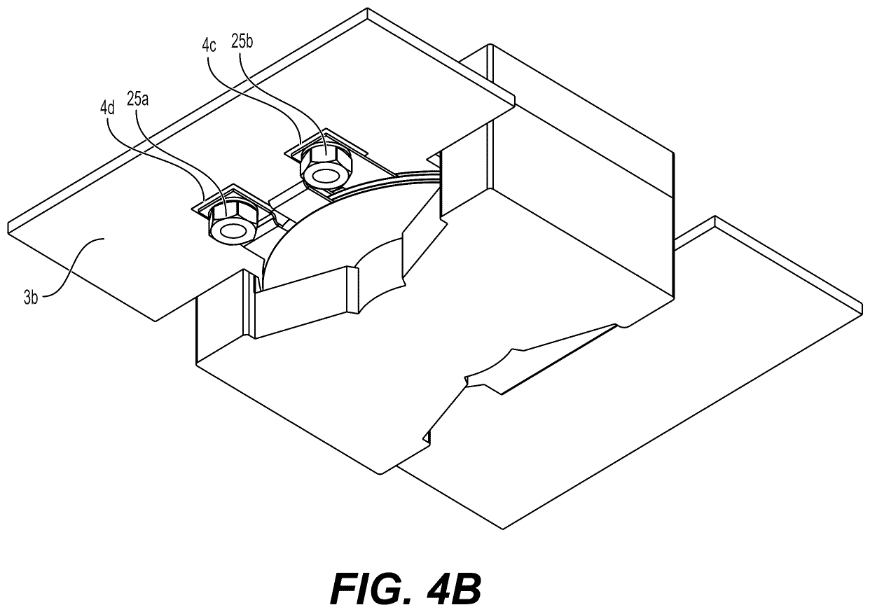

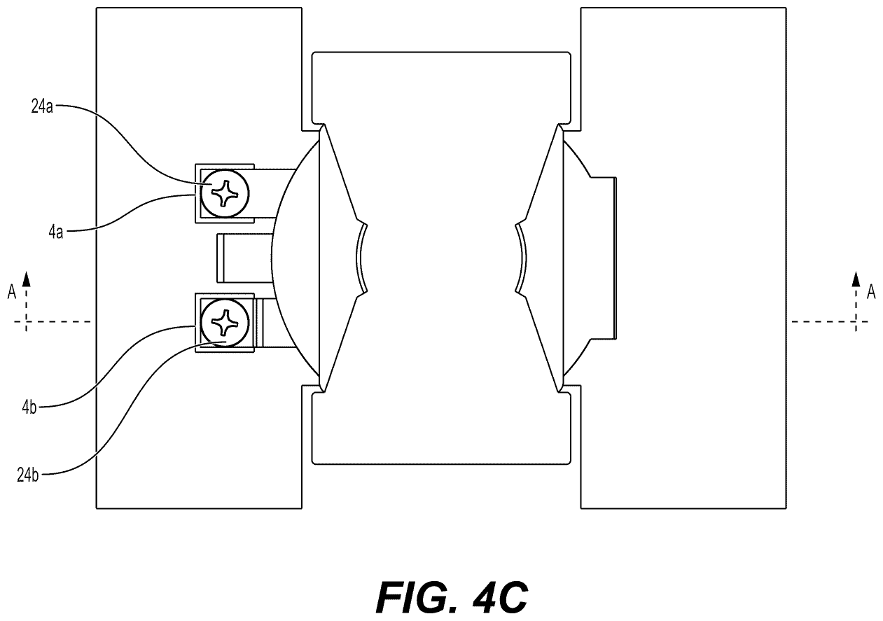

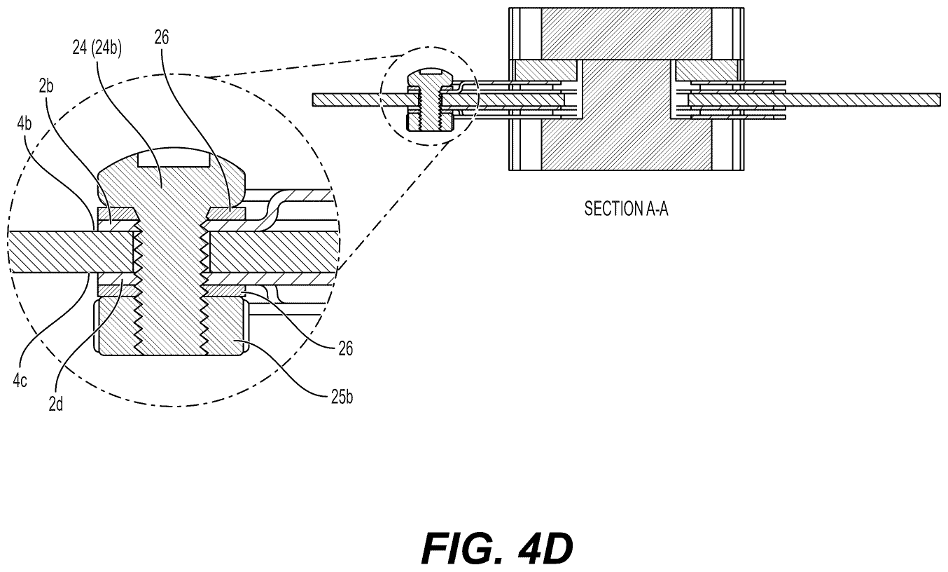

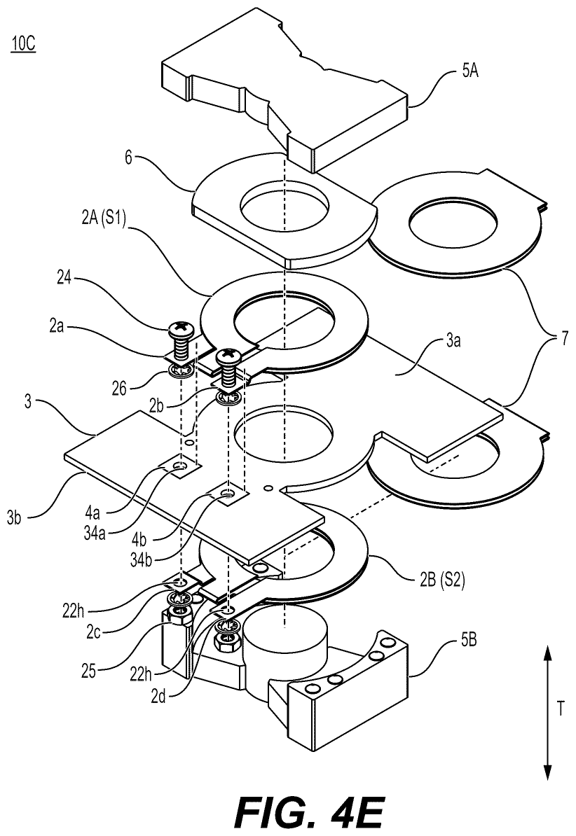

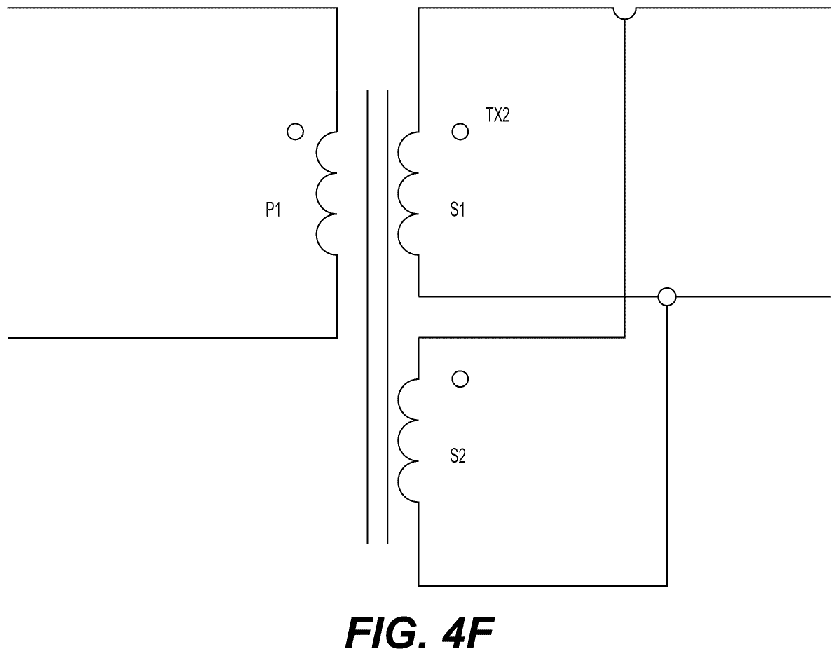

FIGS. 4A-4E show a transformer mounting configuration according to a fourth example embodiment in which the top and bottom copper stamps 2A and 2B of the secondary winding 2 are mounted to the PCB 3 by fasteners, e.g., screws 24 (24a, 24b) and nuts 25 (25a, 25b), and using the same through holes 34a, 34b of the PCB 3. Description and reference characters of some of the same components as those in the first example embodiment will be omitted.

FIG. 4A is an isometric view from above of a transformer 10C according to a fourth example embodiment of the present invention in which two copper stamps 2A, 2B are mounted to a PCB 3 using screws 24 and nuts 25. The two copper stamps 2A, 2B can be mounted to the PCB 3 using any suitable fastener, including, for example, screws/bolts and nuts. FIG. 4B is an isometric view from below of the transformer 10C of FIG. 4A. FIG. 4C is a top view of the transformer 10C of FIG. 4A. FIG. 4D is a cross-sectional view taken along line A-A of the transformer 10C of FIG. 4C. FIG. 4E is an exploded view of the transformer 10C of FIG. 4A according to the fourth example embodiment in which the copper stamps 2A, 2B of the secondary winding 2 are mounted to the top and bottom of the PCB 3 using screws 24 and nuts 25 into the same holes 34a, 34b.

As shown in FIGS. 4A-4E, in the fourth example embodiment, the transformer 10C includes the magnetic core set 5 (5A, 5B), the primary winding P1 which is part of the PCB 3, the secondary winding 2 composed of the two copper stamps 2A and 2B, and mounting hardware including two screws 24 (24a, 24b) and two nuts 25 (25a, 25b) for mounting the copper stamps 2A and 2B. In the fourth example embodiment, the first copper stamp 2A and the second copper stamp 2B have generally the same structure as the copper stamps in the first example embodiment, except that each of the contact portions 2a, 2b, 2c, and 2d is provided with a hole 22h that receives the screw 24 (24a, 24b).

As shown in FIGS. 4A-4E, holes 34a, 34b in the PCB 3 are correspondingly located at the contact pads 4a, 4b. The screws 24 (24a, 24b) extend through the holes 22h of the copper stamps 2A, 2B and the holes 34a, 34b of the PCB 3. In this example embodiment, the screws 24 (24a, 24b) are inserted from the top side of PCB 3 (i.e., at the first main surface 3a) and are secured by nuts 25 (25a, 25b) on the bottom side of the PCB 3 (i.e., at the second main surface 3b). Four washers 26 can be provided with the screws 24 and the nuts 25, as shown in FIGS. 4D and 4E, for example.

FIG. 4F is an equivalent circuit diagram of the transformer 10C according to the fourth example embodiment. As shown in FIG. 4F, the primary winding P1 is magnetically coupled to each of the secondary windings S1(2B) and S2(2A) to form a transformer TX2. In this example, the secondary windings S1(2B) and S2(2A) are connected in parallel.

### Fifth Example Embodiment

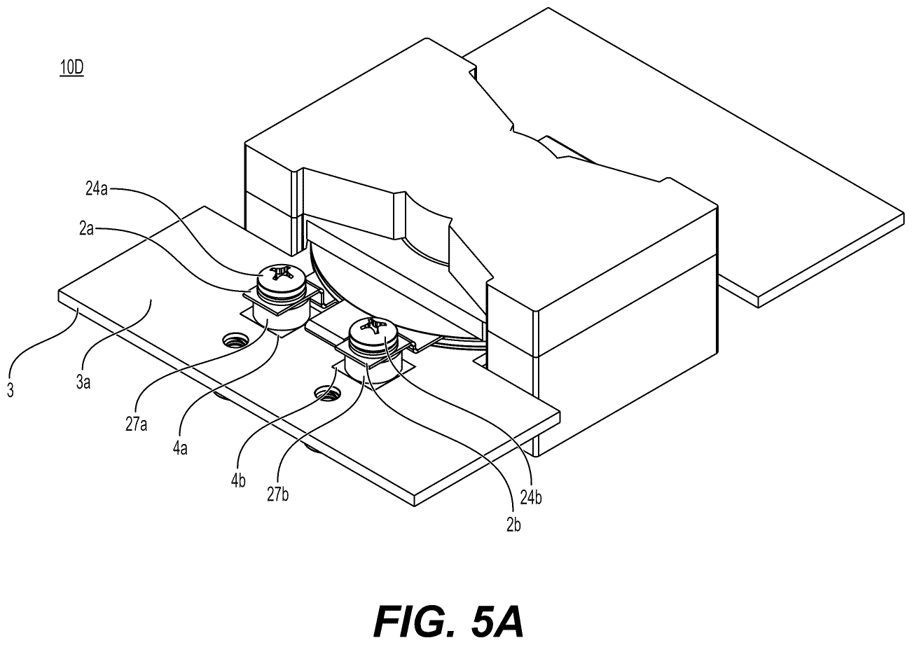

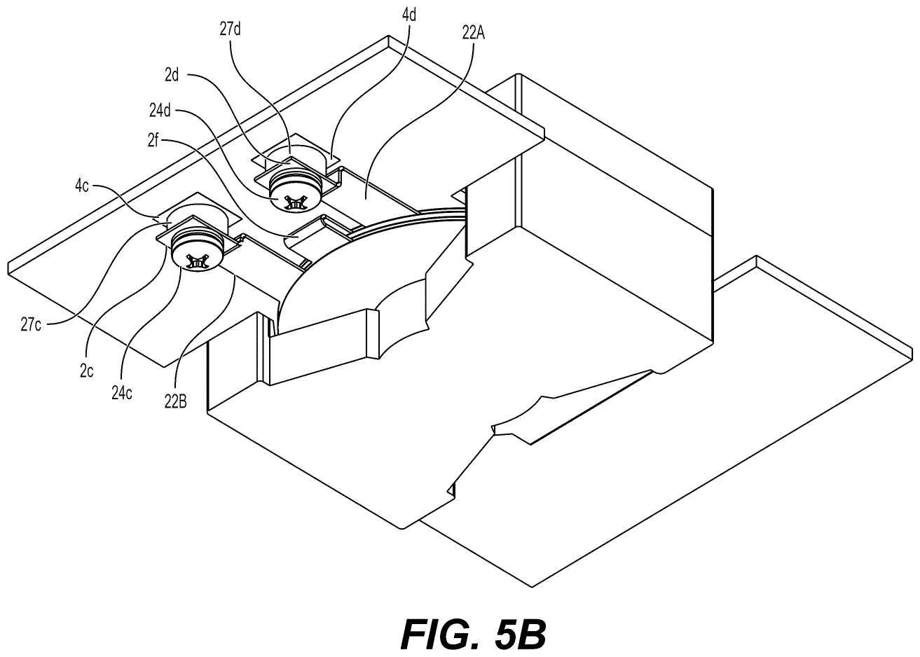

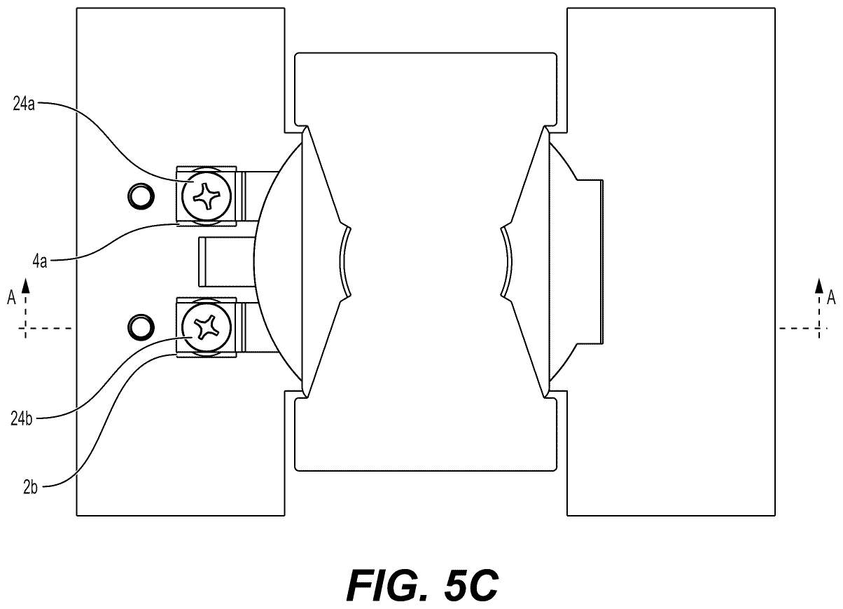

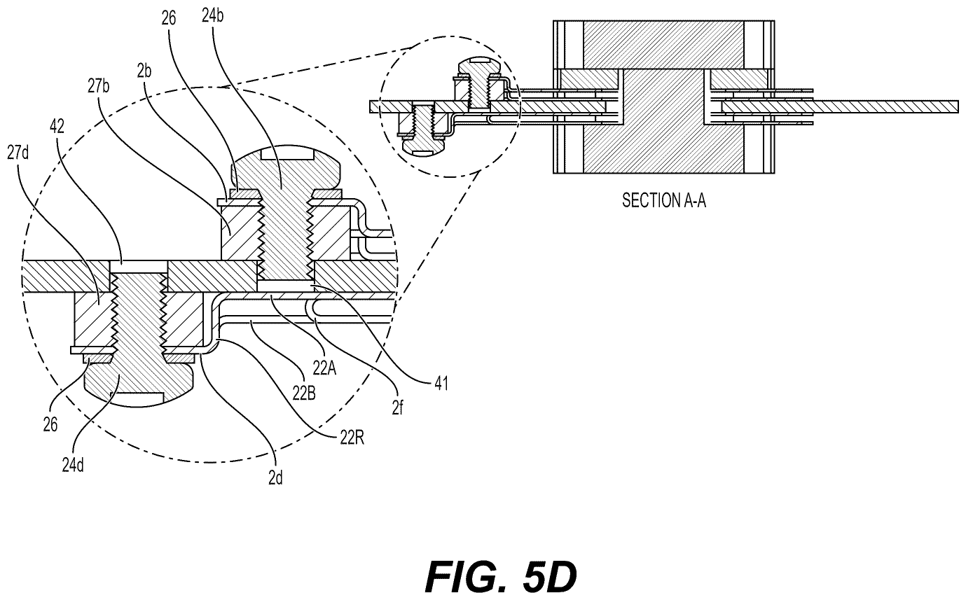

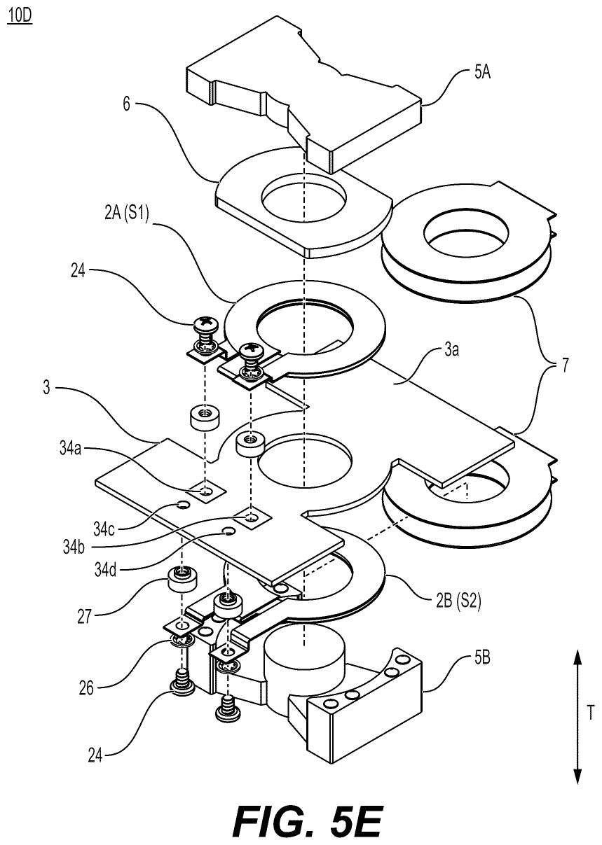

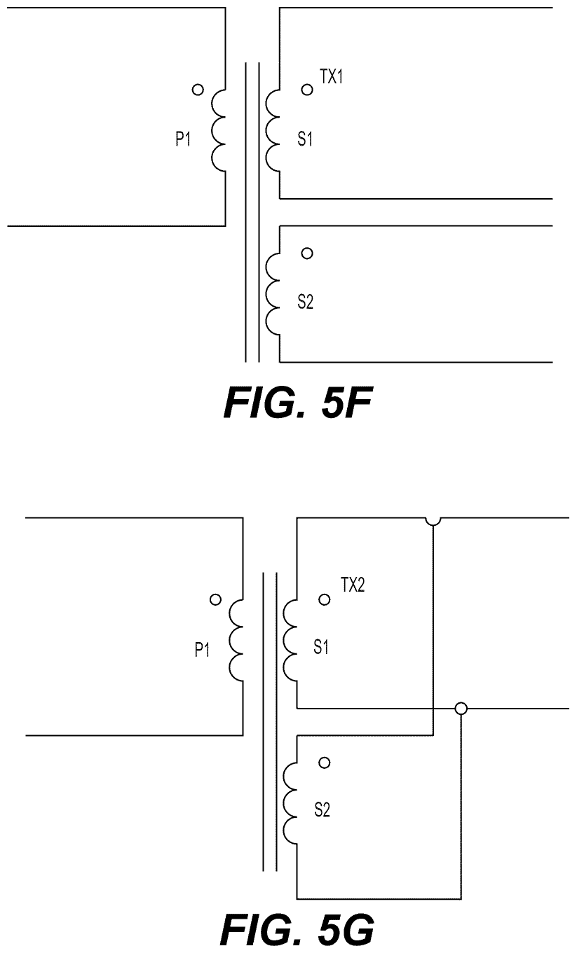

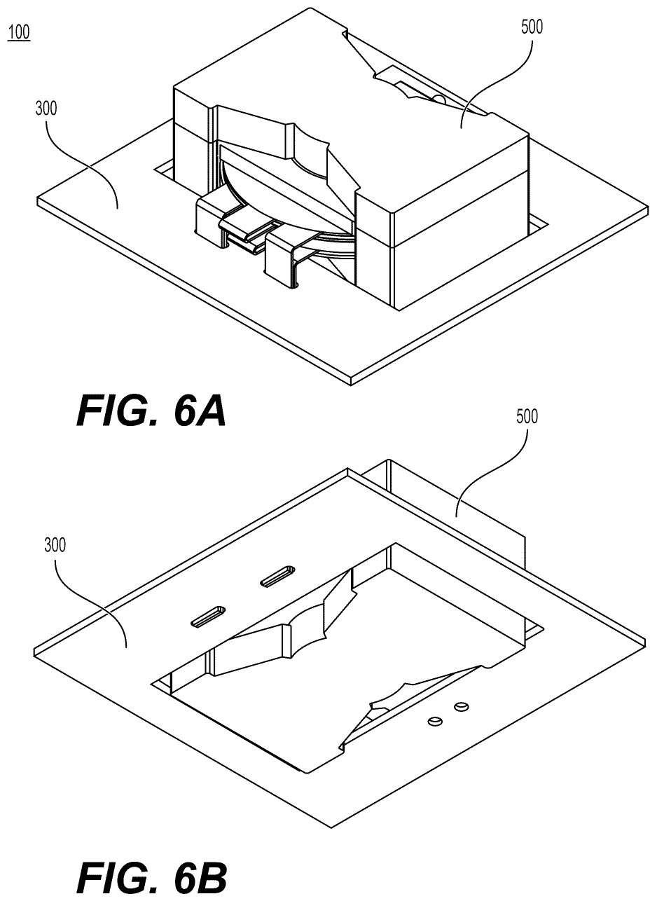

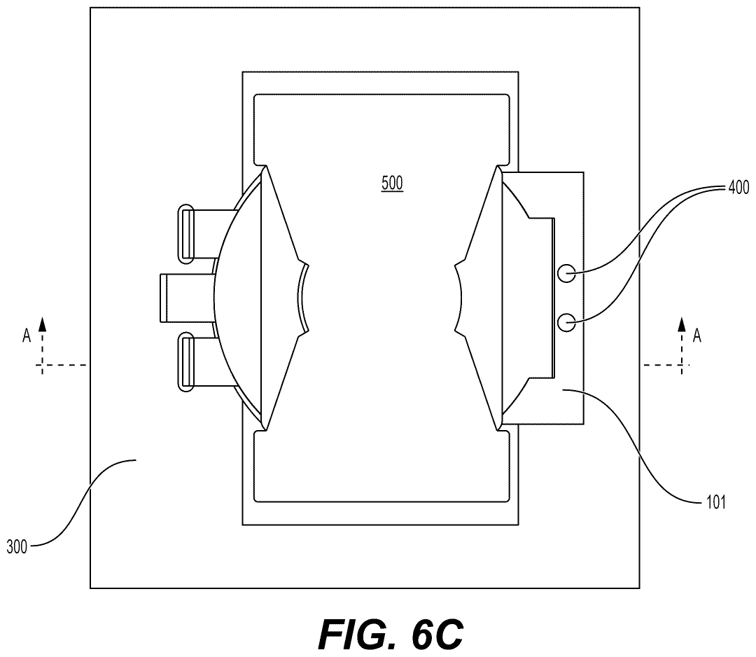

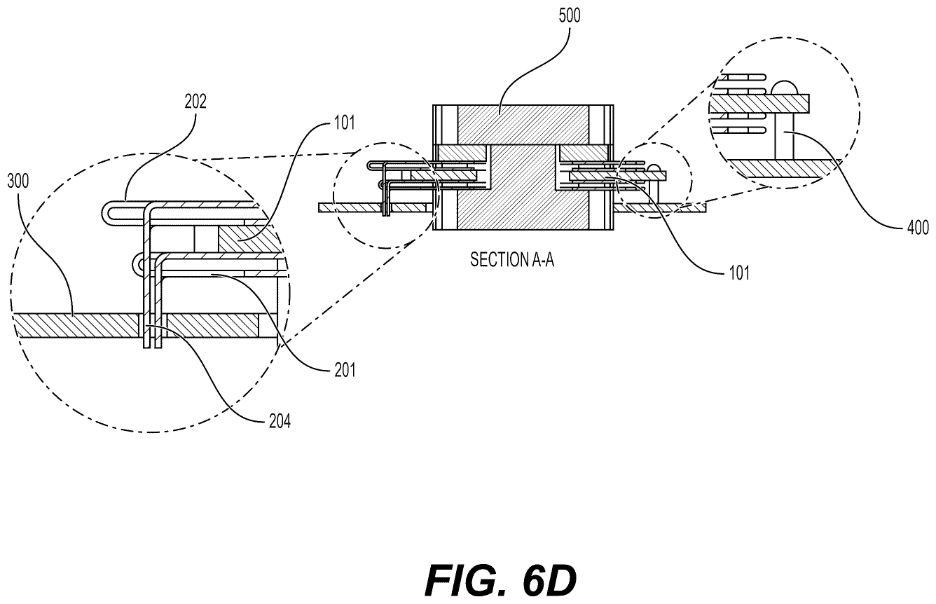

FIGS. 5A-5E show a transformer mounting configuration according to a fifth example embodiment in which the top and bottom copper stamps 2A and 2B of the secondary winding 2 are mounted to the PCB 3 by fasteners, e.g., threaded PCB inserts 27 (27a, 27b, 27c, 27d) and screws 24 (24a, 24b, 24c, 24d), into different through holes 34a, 34b, 34c, 34d. Description and reference characters of some of the same components as those in the above-described example embodiments will be omitted.

FIG. 5A is an isometric view from above of a transformer 10D according to a fifth example embodiment of the present invention in which two copper stamps 2A, 2B are mounted to a PCB 3 using screws 24 and threaded inserts 27. FIG. 5B is an isometric view from below of the transformer 10D of FIG. 5A. FIG. 5C is a top view of the transformer 10D of FIG. 5A. FIG. 5D is a cross-sectional view taken along line A-A of the transformer 10D of FIG. 5C. FIG. 5E is an exploded view of the transformer 10D of FIG. 5A according to the fifth example embodiment in which the copper stamps 2A, 2B of the secondary winding are mounted to the top and bottom of the PCB 3 using screws 24 and threaded inserts 27.

As shown in FIGS. 5A-5E, in the fifth example embodiment, the transformer 10d includes the magnetic core set (5A, 5B), the primary winding P1 which is part of the PCB 3, the secondary winding 2 composed of the two copper stamps 2A and 2B, and hardware including four screws 24 (24a, 24b, 24c, 24d) and four threaded inserts 27 (27a, 27b, 27c, 27d) for mounting the copper stamps 2A and 2B.

The threaded PCB inserts 27 can be made of an electrically conductive material. In addition, or alternatively, the screws 24 may be made of an electrically conductive material.

As shown in FIGS. 5A-5E, third and fourth holes 34c, 34d are provided in the PCB 3, in addition to the first and second holes 34a, 34b. The threaded PCB inserts 27 (27a, 27b, 27c, 27d) are screwed into the holes 34a, 34b, 34c, 34d of PCB 3, respectively. The contact portions 2a, 2b of first (top) copper stamp 2A are raised and bent to a height in accordance with a thickness of the threaded PCB inserts 27a, 27b. Likewise, the contact portions 2c, 2d of the second (bottom) copper stamp 2B are raised (towards the bottom direction) and bent to a height in accordance with a thickness of the threaded PCB inserts 27c, 27d. As shown in FIG. 5D, the second copper stamp 2B includes a raised bent portion 22R that is connected between the contact portion 2d and the first layer 22A of the second copper stamp 2B. As shown in FIGS. 5D and 5E, the through-hole 34b may include a conductive contact 41, and the through-hole 34d may include a conductive contact 42. The conductive contacts 41 and 42 provide connection to other conductive traces (not shown) within the PCB 3.

According to the fifth example embodiment described above, the copper stamps 2A, 2B of the secondary winding 2 are mounted to the top and bottom of the PCB 3 using screws 24 and threaded inserts 27 and different holes 34a, 34b, 34c, 34d of the PCB 3.

FIG. 5F is an equivalent circuit diagram of the transformer 10D according to the fifth example embodiment in a first circuit configuration. As shown in FIG. 5F, the primary winding P1 is magnetically coupled to each of the secondary windings S1(2B) and S2(2A) to form a transformer TX1. The two secondary windings S1(2B) and S2(2A) are independent within the transformer TX1 as shown in FIG. 5F. However, the two secondary windings S1(2B) and S2(2A) can be connected in parallel or in series with each other depending on the connections in an external circuit connected to the transformer TX1.

FIG. 5G is an equivalent circuit diagram of the transformer 10D according to the fifth example embodiment in a second circuit configuration. As shown in FIG. 5G, the primary winding P1 is magnetically coupled to each of the secondary windings S1(2B) and S2(2A) to form a transformer TX2. In this alternative example, the secondary windings S1(2B) and S2(2A) are connected in parallel.

### Main PCB Example Embodiment

FIG. 7A is an isometric view showing a plurality of transformers 110 mounted on a main circuit board 303 according to an example embodiment of the present invention. In this example, three transformers 110 are mounted on the main circuit board 303, and the components of one of the transformers 110 is provided in an exploded view. Each of the transformers 110 may correspond to, and include all of the components of, any one of the transformers 10, 10A, 10B, 10C, or 10D as previously described. The main circuit board 303 can be any suitable substrate, including, for example, a PCB that corresponds to, but is larger than, the PCB 3 as previously described in the above examples. The main circuit board 303 may be part of a larger module, such as an electronic module, including, for example, a DC-DC converter module. In this example, the main circuit board 303 is a PCB that includes three respective primary windings (not shown) that are embedded within the main circuit board 303, each of which are sandwiched by the copper stamps 2A and 2B of the secondary winding 2, as similarly described in the previous examples of the transformers 10, 10A, 10B, 10C, or 10D. Of course, any number of transformers 10, 10A, 10B, 10C, or 10D may be mounted on the main circuit board 303.

FIG. 7B is a plan view of FIG. 7A. In this example, three transformers 110 are adjacently mounted in a row on the main circuit board 303. As shown in FIGS. 7A and 7B, adjacent transformers 110 that are directly next to each other may share the same cutout 9A or 9B. Such configuration allows saving of space on the main circuit board 303 and allows multiple transformers 110 to be mounted in a compact area of a larger circuit board module.

FIGS. 7C and 7D show an electronic module that shows electronic components 350 on the main circuit board 303. The electronic components 350 can be any suitable components, including passive components, such as resistors, capacitors, inductors, etc., and including active components, such as transistors, integrated circuits, etc. The electronic components 350 can be used to implement the functions of the electronic module.

The transformers 110 can be integrated and mounted to main circuit board 303 so that multiple secondary connections can be provided for each primary winding. As explained above, in some example embodiments, the copper stamps 2A, 2B can be connected to the same through-holes to reduce the number of manufacturing steps. The cost of manufacturing can be reduced by using the main circuit board 303 for the primary windings, and the secondary winding manufacturing, especially for high current secondary windings that include copper stamps, can be streamlined.

With the structure and configurations according to the example embodiments of the present invention described above, it possible to provide transformers which reduce the cost of manufacturing by employing the PCB for the primary winding and various mounting techniques to streamline secondary winding manufacturing, especially for high current secondary windings that include copper stamps. Moreover, the transformers according to the example embodiments of the present invention described above provide a robust structure with reduced profile that is easy to assemble.

It should be understood that the foregoing description is only illustrative of the present invention. Various alternatives and modifications can be devised by those skilled in the art without departing from the present invention. Accordingly, the present invention is intended to embrace all such alternatives, modifications, and variances that fall within the scope of the appended claims.

What is claimed is:

1. A transformer comprising:
a printed circuit board including a first main surface and a second main surface that are opposed to each other in a thickness direction of the printed circuit board;
a primary winding provided in the printed circuit board;
a secondary winding defined by a first copper stamp provided on the first main surface of the printed circuit board and a second copper stamp provided on the second main surface of the printed circuit board; and
a magnetic core; wherein the primary winding is sandwiched by the first copper stamp and the second copper stamp;
a first portion of the magnetic core extends through a coil opening of each of the primary winding and the secondary winding in the thickness direction;
a second portion of the magnetic core overlaps with each of the primary winding and the secondary winding in the thickness direction;
a third portion of the magnetic core extends through a first cutout of the printed circuit board in the thickness direction; and
a fourth portion of the magnetic core extends through a second cutout of the printed circuit board in the thickness direction.

2. The transformer according to claim 1, wherein the first copper stamp and the second copper stamp are surface mounted to the printed circuit board.

3. The transformer according to claim 1, wherein the first copper stamp and the second copper stamp are connected through same through-holes of the printed circuit board.

4. The transformer according to claim 1, wherein the first copper stamp and the second copper stamp are connected to different through-holes of the printed circuit board.

5. The transformer according to claim 1, wherein the first copper stamp and the second copper stamp are connected by screws extending through same through-holes of the printed circuit board.

6. The transformer according to claim 1, wherein the first copper stamp and the second copper stamp are connected by screws extending through different through-holes of printed circuit board.

7. The transformer according to claim 1, wherein
a first insulation material is provided between the first copper stamp and the magnetic core; and
a second insulation material is provided between the printed circuit board and the second copper stamp.

8. The transformer according to claim 1, wherein a spacer is provided between the first copper stamp and the magnetic core.

9. A circuit board module comprising:
a printed circuit board including a first main surface and a second main surface that are opposed to each other in a thickness direction of the printed circuit board; and
a plurality of transformers integrated and mounted on the printed circuit board; wherein each of the plurality of transformers includes:
a primary winding provided in the printed circuit board;
a secondary winding defined by a first copper stamp provided on the first main surface of the printed circuit board and a second copper stamp provided on the second main surface of the printed circuit board; and
a magnetic core; wherein
in each of the plurality of transformers:
the primary winding is sandwiched by the first copper stamp and the second copper stamp;
a first portion of the magnetic core extends through a coil opening of each of the primary winding and the secondary winding in the thickness direction;
a second portion of the magnetic core overlaps with each of the primary winding and the secondary winding in the thickness direction;
a third portion of the magnetic core extends through a first cutout of the printed circuit board in the thickness direction; and
a fourth portion of the magnetic core extends through a second cutout of the printed circuit board in the thickness direction.

10. The circuit board module according to claim 9, wherein
the plurality of transformers includes a first transformer and a second transformer that are adjacent to each other; and
the third portion of the magnetic core of the first transformer and the fourth portion of the magnetic core of the second transformer share a same cutout of the printed circuit board.

11. An electronic module comprising:
a substrate including a substrate opening and first and second cutouts;
an electronic component located on the substrate; and
a transformer connected to the electronic component and including:
a primary winding on or in the substrate that extends around the substrate opening;
a secondary winding connected to the substrate and including first and second stamps on opposing sides of the substrate, each of the first and the second stamps includes a stamp opening; and
a magnetic core that extends through the substrate opening, through the second and the third cutouts, and through each stamp opening in the first and the second stamps.

12. The electronic module of claim 11, wherein the first and the second stamps are surface mounted to the substrate.

13. The electronic module of claim 11, wherein the substrate includes through holes.

14. The electronic module of claim 13, wherein the first and the second stamps extend through different through holes.

15. The electronic module of claim 13, wherein the first and the second stamps extend through same through holes.

16. The electronic module of claim 13, further comprising fasteners that extend through the through holes to connect the first and the second stamps to the substrate.

17. The electronic module of claim 16, wherein different fasteners connect the first and the second stamps to the substrate.

18. The electronic module of claim 16, wherein same fasteners connect the first and the second stamps to the substrate.

19. The electronic module of claim 11, further comprising an additional transformer that includes an additional magnetic core; wherein
the additional magnetic core extends through the third cutout adjacent to the magnetic core.

20. The electronic module of claim 11, wherein the electronic module is a power module.
